(19) United States
(12) Patent Application Publication
(10) Pub. No.: US 2024/0404791 A1
(43) Pub. Date: Dec. 5, 2024

(54) POWER DELIVERY USING MICROWAVE SOURCE

(71) Applicant: ASM IP HOLDING B.V., ALMERE (NL)

(72) Inventor: Imran Ahmed BHUTTA, Moorestown, NJ (US)

(21) Appl. No.: 18/673,784

(22) Filed: May 24, 2024

Related U.S. Application Data
(60) Provisional application No. 63/504,922, filed on May 30, 2023.

(51) Int. Cl. H01J 37/32

(52) U.S. Cl. CPC H01J 37/32183; H01J 37/32137

(57) ABSTRACT

In one embodiment, the present disclosure is directed to a system for controlling microwave power delivered to a distributed electrode to improve the uniformity of an electric field on the distributed electrode. The system includes an RF source circuit comprising at least one RF generator and multiple RF source circuit outputs, each RF source circuit output outputting an RF source signal having a frequency of at least 300 MHz. For each of the RF source circuit outputs, a solid-state impedance matching circuit is operably coupled to the RF source circuit output and configured to receive the RF source signal output by the RF source circuit output. For each of the matching circuits, a system output is operably coupled to the matching circuit and configured to output the RF source signal to a distributed electrode of the load.

### BACKGROUND

In a semiconductor fabrication system, one approach for reducing film deposition or etch times is to use a higher density plasma (HDP). One method for creating HDP is to increase the frequency of the RF source. As the frequency of the RF source is increased, however, its wavelength decreases and can become comparable to the dimensions in the plasma chamber. A microwave HDP source, such as one operating at 2.45 GHZ, can have wavelengths of approximately 120 mm in vacuum and less (20-70 mm) in plasma. Over this wavelength, the electric field can be very non-uniform. With a 300 mm wafer, the variation of the electric field over the electrode, and consequently in the plasma, can also be very non-uniform. There is a need to make this electric field more uniform and thus provide better uniformity of deposited film or etch over the surface of the wafer.

### BRIEF SUMMARY

The present disclosure may be directed, in one aspect, to a system including a radio frequency (RF) source circuit comprising at least one RF generator and multiple RF source circuit outputs, each RF source circuit output outputting an RF source signal having a frequency of at least 300 MHz; for each of the RF source circuit outputs, a solid-state impedance matching circuit operably coupled to the RF source circuit output and configured to receive the RF source signal output by the RF source circuit output; and electronically alter its impedance to enable an impedance match between the RF source circuit output and a load; and for each of the matching circuits, a system output operably coupled to the matching circuit and configured to output the RF source signal to a distributed electrode of the load.

In another aspect, a method to control microwave power delivered to a distributed electrode to improve the uniformity of an electric field on the distributed electrode is disclosed. The method includes an RF source circuit outputting, at each of multiple RF source circuit outputs, an RF source signal having a frequency of at least 300 MHz; for each of the RF source circuit outputs, receiving, at a solid-state impedance matching circuit, the RF source signal and electronically altering the matching circuit's impedance to enable an impedance match between the RF source circuit output and a load; and the matching circuits outputting the RF source signals to a distributed electrode of the load.

In another aspect, a semiconductor processing system includes a distributed electrode; and a power delivery system comprising a radio frequency (RF) source circuit comprising at least one RF generator and multiple RF source circuit outputs, each RF source circuit output outputting an RF source signal having a frequency of at least 300 MHz; for each of the RF source circuit outputs, a solid-state impedance matching circuit operably coupled to the RF source circuit output and configured to receive the RF source signal output by the RF source circuit output; and electronically alter its impedance to enable an impedance match between the RF source circuit output and a load, the distributed electrode forming part of the load; and for each of the matching circuits, a system output operably coupled to the matching circuit and configured to output the RF source signal to the distributed electrode of the load.

While the disclosed inventions are applicable to semiconductor fabrication systems, the invention is not so limited.

### BRIEF DESCRIPTION OF THE DRAWINGS

The present disclosure will become more fully understood from the detailed description and the accompanying drawings, wherein:

FIG. 1 is a schematic of a system for fabricating a semiconductor according to one embodiment.

FIG. 2 is a schematic of a system for fabricating a semiconductor utilizing a power delivery system according to one embodiment.

FIG. 3 is a schematic of an alternative RF source circuit according to one embodiment.

FIG. 4 is a schematic of signal generators according to another embodiment.

FIGS. 5-6 are drawings of distributed electrodes according to different embodiments.

FIG. 7 is a schematic of a system for fabricating a semiconductor utilizing variable capacitors according to one embodiment.

FIG. 8 is a schematic of an electronically variable capacitor according to one embodiment.

FIG. 9 is a schematic of a system for fabricating a semiconductor utilizing magnetic coupling according to one embodiment.

The drawings represent one or more embodiments of the present invention(s) and do not limit the scope of invention.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to the interpretation “based entirely on.” Furthermore, the term “each,” when used in reference to each of a plurality of items, need not refer to each such item in an entire system or apparatus, but may instead simply refer to each of the recited one or more such items in the system.

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

In the following description, where block diagrams or circuits are shown and described, one of skill in the art will recognize that, for the sake of clarity, not all peripheral components or circuits are shown in the figures or described in the description. For example, common components such as memory devices and power sources may not be discussed herein, as their role would be easily understood by those of ordinary skill in the art. Further, the terms “couple” and “operably couple” can refer to a direct or indirect coupling of two components of a circuit.

It is noted that for the sake of clarity and convenience in describing similar components or features, the same or similar reference numbers may be used herein across different embodiments or figures. This is not to imply that the components or features identified by a particular reference number are identical across each embodiment or figure, but only to suggest that the components or features are similar in general function or identity.

Features of the present inventions may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. As used herein, the term “processor” may refer to one or more processors.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present inventions may be embodied in the form of computer-implemented processes and apparatuses such as processor-based data processing and communication systems or computer systems for practicing those processes. The present inventions may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

### Semiconductor Processing System

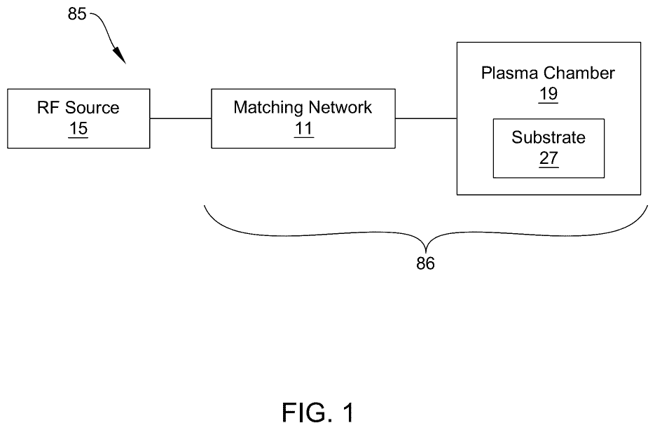

Referring to FIG. 1, a semiconductor device processing system 5 utilizing an RF generator 15 is shown. The system 85 includes an RF generator 15 and a semiconductor processing tool 86. The semiconductor processing tool 86 includes a matching network 11 and a plasma chamber 19. In other embodiments, the generator 15 or other power source can form part of the semiconductor processing tool. Commonly owned U.S. Pat. No. 9,345,122, the disclosure of which is incorporated herein by reference in its entirety, provide examples of generators that may be applied to the generators discussed herein.

The semiconductor device can be a microprocessor, a memory chip, or other type of integrated circuit or device. A substrate 27 (such as a wafer) can be placed in the plasma chamber 19, where the plasma chamber 19 is configured to deposit a material layer onto the substrate 27 or etch a material layer from the substrate 27. Plasma processing involves energizing a gas mixture by imparting energy to the gas molecules by introducing RF energy into the gas mixture. This gas mixture is typically contained in a vacuum chamber (the plasma chamber 19), and the RF energy is typically introduced into the plasma chamber 19 through electrodes. Thus, the plasma can be energized by coupling RF power from an RF source 15 into the plasma chamber 19 to perform deposition or etching.

In a typical plasma process, the RF generator 15 generates power at a radio frequency and this power is transmitted through RF cables and networks to the plasma chamber 19. In a preferred embodiment, the frequency is a microwave frequency, such as 2.45 GHZ, or 2-3 GHZ, or at least 300 MHz, or at least 800 MHZ.

In order to provide efficient transfer of power from the RF generator 15 to the plasma chamber 19, an intermediary circuit is used to match the fixed impedance of the RF generator 15 with the variable impedance of the plasma chamber 19. Such an intermediary circuit is commonly referred to as an RF impedance matching network, or more simply as an RF matching network.

The purpose of the RF matching network 11 is to transform the variable plasma impedance to a value that more closely matches the fixed impedance of the RF generator 15. Commonly owned U.S. Publication Nos. 2021/0183623 and 2021/0327684, the disclosures of which are incorporated herein by reference in their entirety, provide examples of such matching networks.

### Microwave Power Delivery System

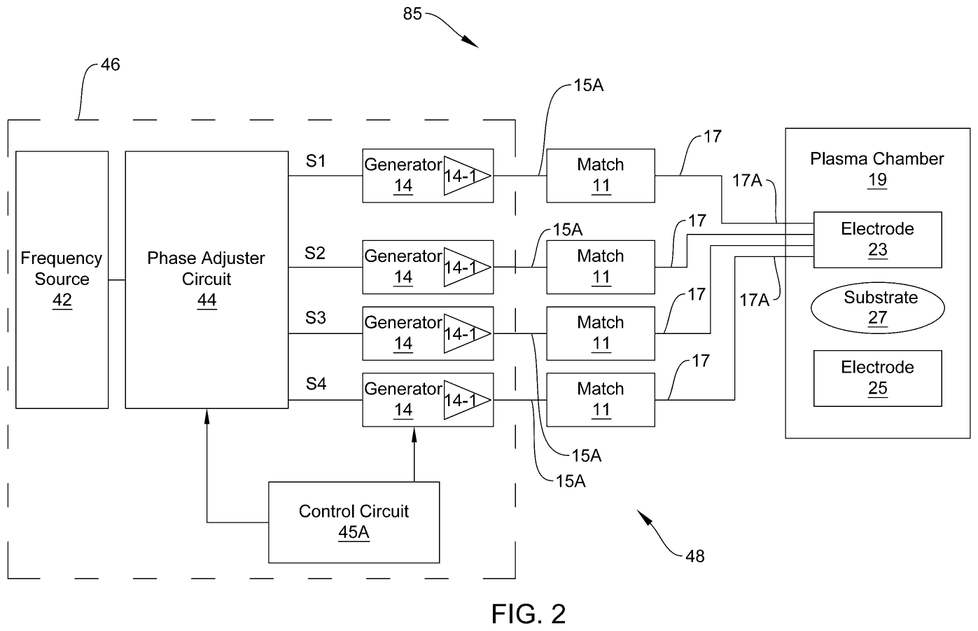

FIG. 2 is a schematic of a system for fabricating a semiconductor utilizing a microwave power delivery system according to one embodiment. In this embodiment, the system 85 comprises a plasma chamber 19 and a power delivery system 48. The plasma chamber 19 includes a first electrode 23 and a second electrode 25, and in processes that are well known in the art, the first and second electrodes 23, 25, in conjunction with appropriate control systems (not shown) and the plasma in the plasma chamber, enable deposition of materials onto a substrate 27 and/or etching of materials from the substrate 27.

The power delivery system 48 includes an RF source circuit 46 and matching networks 11. The power delivery system 48 also includes a control circuit 45A, which may include a processor such as those discussed herein. The control circuit 45A controls the RF source circuit and may also control the matching networks 11. In this embodiment, the control circuit 45 controls the frequency source 42, the phase adjuster circuit 44, and each of the generators 14, while the matching networks 11 have their own control circuits. The generators 14 may also have their own control circuits.

The RF source circuit 46 may have certain features similar to the RF sources as discussed above with reference to FIG. 1. In the exemplified embodiment, the RF source circuit 46 includes at least one RF generator 14 and multiple RF source circuit outputs 15A each outputting an RF source signal having a frequency of at least 300 MHz. In this embodiment, there are four RF generators 14, but there may be more or less. In the exemplified embodiment, each RF source signal is originated by a separate one of the RF generators 14, but the invention is not so limited. Each generator 14 may include an amplifier 14-1 configured to amplify a received RF signal. Those amplifiers may be controlled by a common control circuit, such as control circuit 45A.

For each of the RF source circuit outputs 15A, a solid-state impedance matching circuit 11 is operably coupled to the RF source circuit output and configured to receive the RF source signal output by the RF source circuit output, electronically alter its impedance to enable an impedance match between the RF source circuit output and a load. This impedance matching process is discussed in more detail below. In other embodiments, the impedance matching circuit could impedance match in a non-electronic, non-solid-state manner, such as by using vacuum variable capacitor that utilizes a motor. In yet other embodiments, one or more of the matching networks could be non-variable or fixed, such that the matching network does not provide a variable impedance.

For each of the matching circuits 11, a power delivery system output 17 is operably coupled to an output of the matching circuit 11 and configured to output the RF source signal to a distributed electrode 23 of the load. Note that the system output 17 need not be directly connected to the output of the matching circuit 11.

The power delivery system 48 may also enable phase control. In the exemplified system, the RF source circuit 46 includes a frequency source 42 and a phase adjuster circuit 44. The frequency source 42 is configured to transmit a signal to the phase adjuster circuit. The phase adjuster circuit 44 (which may comprise one or more circuits, and may be combined with the frequency source) is configured to output to each of the at least one RF generators 14 a separate RF signal. For example, the phase adjuster circuit 44 may transmit a first RF signal SI to a first generator, a second RF signal S2 to a second generator, a third RF signal S3 to a third generator, and a fourth RF signal S4 to a fourth generator. In the exemplified embodiment, each of the separate RF signals S1, S2, S3, S4 has a different phase, and the frequency source 42 and phase adjuster circuit 44 are upstream of the at least one RF generator. The phase adjuster circuit 44 may be configured to phase lock the phase of each RF source signal. The phase locking may be carried out, for example, using an off-the-shelf integrated circuit, such as Analog Devices' ADF4002BCPZ or Texas Instrument's CD74HCT7046AM96. Using such a circuit, the system may input a reference signal and a sampled signal and output an error signal that keeps the phase locked to the reference signal. Further, the phase adjuster circuit 44 may be configured to adjust the phase of each RF source signal based on phase-related information obtained from either the distributed electrode 23, an output of one or more of the matching circuits 17, an input of one or more of the matching circuits 17, an output of one or more of the at least one RF generator 14, or an input of one or more of the at least one RF generator 14. It is noted that, since that the communication/connections necessary for this adjustment would be easily understood by one of ordinary skill in the art, the connections are not shown in drawings. It is further noted that the invention is not limited to the foregoing embodiments for phase control.

### Alternative RF Source Circuits

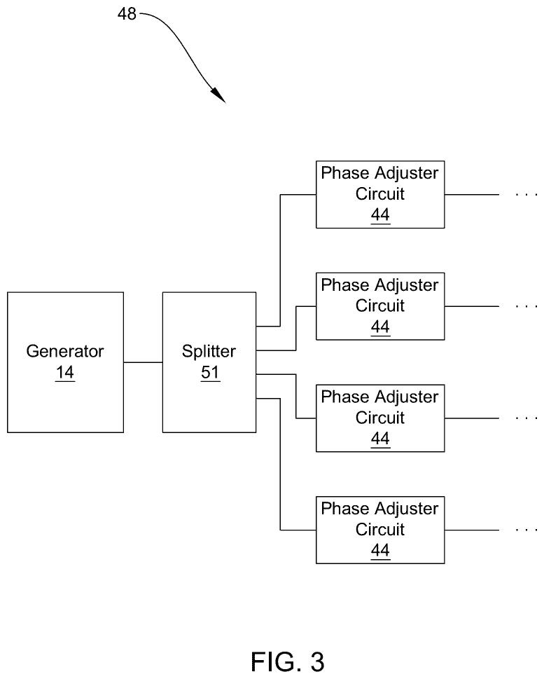

FIG. 3 is a schematic of an alternative RF source circuit 48 according to one embodiment. In this RF source circuit 48, rather than having multiple generators, there is only a single generator 14, which provides an RF signal to a splitter 51. The splitter 51 splits the received signal into multiple signals (four in this embodiment), and provides those signals to phase adjust circuits 44 that can adjust the phase of the received signals as discussed herein.

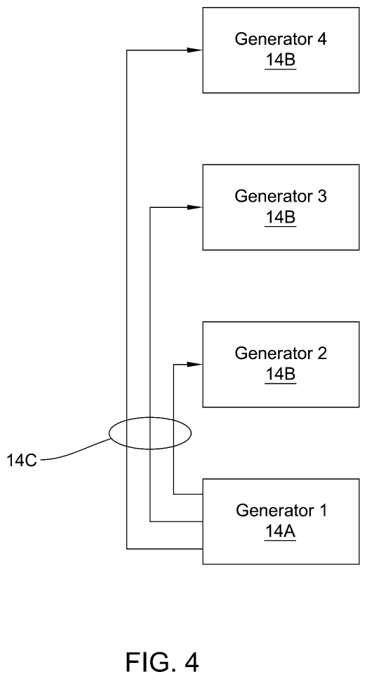

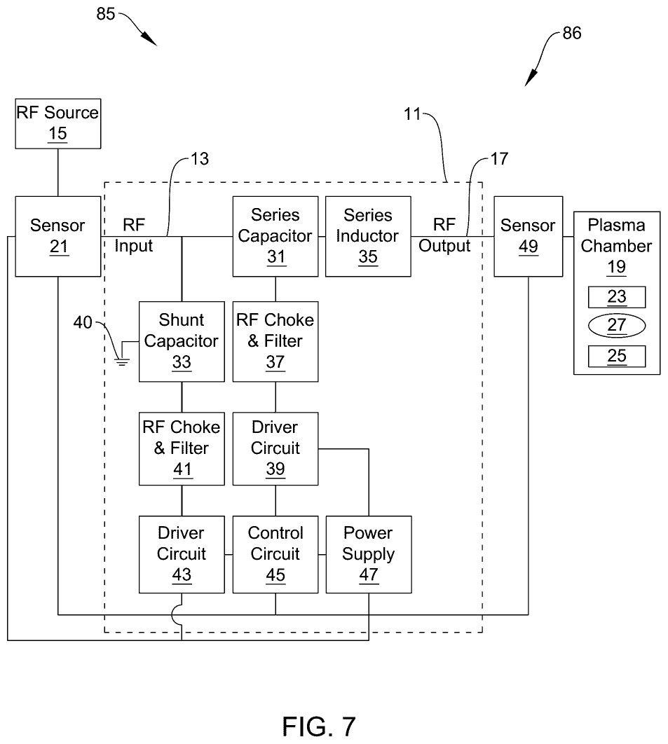

FIG. 4 is a schematic of signal generators according to another embodiment. This embodiment is similar to that shown in FIG. 7 of co-owned U.S. Publication No. 2010/0123502, which is incorporated herein by reference in its entirety. In this embodiment, the RF source circuit includes generators 14A, 14B. Generator 14A provides output phase information to the other generators 14B to enable phase control via phase signals 14C. Thus, generator 14A can be designated the master, and the other generators 14B can be designated slaves. The phase information can be machine code, low level RF (also known as common exciter oscillator or CEX), a combination of the two, or some other component or signal that transmits phase information between signal generators. The master signal generator 14A can coordinate the phase control of the other signal generators 14B so that their respective outputs have substantially the same or different phases. Although four signal generators are shown, the number is exemplary only and not meant to be limiting. Alternatively, a single signal generator with multiple outputs may be used instead of the signal generators 14A, 14B.

In the embodiment shown, the master signal generator 14A is substantially similar to the slave signal generators 14B. However, the master signal generator 14A can adjust, for example, the phase shift from approximately 0° to approximately 360°, the incremental change in the phase from approximately 0.01° to approximately 360°, and the time period between incremental changes in the phase from approximately 1 microsecond to approximately 100minutes. The slave signal generators 14B substantially follow the master signal generator 14A. Each of the slave signal generators 14B can have their own independent control loop and power measurement.

### Distributed Electrode

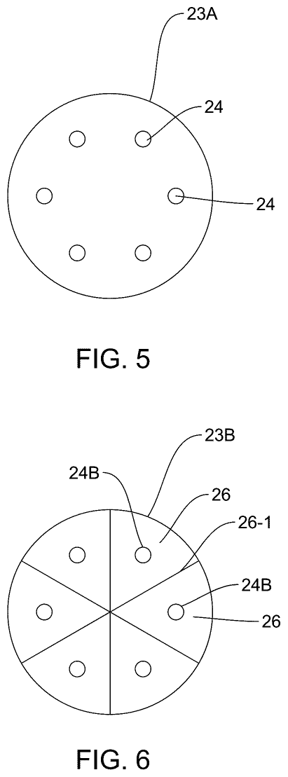

FIGS. 5-6 are drawings of distributed electrodes according to different embodiments. FIG. 5 shows a multi-feed distributed electrode 23A made of a single electrode comprising multiple feeds 24 (e.g., patch antennas or other electrodes) at different locations, each of the feeds receiving a separate one of the RF source signals. The number, size, and location of the feeds may vary. In this example, the feeds 24 are 60 degrees apart, being evenly spaced azimuthally around the center of the distributed electrode 23A.

FIG. 6, by contrast, shows a segmented distributed electrode 23B made up of a plurality of electrode segments 26 adjacent to one another and separated by dielectric material 26-1, each of the plurality of electrodes segments receiving a separate one of the RF source signals via a feed 24B. The number, size, and location of the feeds and the electrode may vary.

As discussed above with reference to FIG. 2, the exemplified load is a plasma chamber 19 that includes a first electrode 23 and a second electrode 25 that enables the deposition and/or etching of materials from a substrate 27. One or both of these electrodes 23, 25 may be the distributed electrode discussed herein that receives the RF source signals. This is shown in FIG. 2 with the system outputs 17 being coupled to electrode 23. In this embodiment, the electrode 25 is a chuck for holding the substrate 27 and/or providing electrostatic (ESC) functionality. The number, size, and location of the segments and feeds, and the electrode, may vary.

In one example, a dielectric plate is located over the distributed electrode to distribute received energy to the electrode. The dielectric plate includes a circular face and N number of receiving areas positioned at an equal distance from a center of the dielectric plate. The N receiving areas are evenly spaced azimuthally around the center of the dielectric plate. The location of the receiving areas is similar to the locations of the feeds 24 shown in FIG. 5. Microwave energy may be directed from waveguides, to the receiving areas of the dielectric plate, and then distributed to the distributed electrode.

In certain embodiments, the distributed electrode may receive the RF source signals via a conductor 17A (see FIG. 2) operably coupled to the system output 17, the conductor 17A being directly physically connected to the distributed electrode 23, 23A, 23B. In other embodiments, the distributed electrode may receive the RF source signals via a conductor similar to conductor 17A, being operably coupled to the system output, but being positioned in close proximity to the distributed electrode (or in close proximity to a dielectric plate over the distributed electrode, such as the dielectric plate discussed above) without the conductor physically contacting the distributed electrode (or dielectric plate), such that the RF power may be launched from the conductor to the feeds 24, 24B (or the receiving areas of the dielectric plate). Such close proximity is not shown in the drawings but, in view of the rest of the disclosure, including FIG. 2 and illustrated conductors 17A, would be readily understood by a person of ordinary skill in the art.

### Impedance Matching Using Variable Reactance Elements

The matching circuits 11 of FIG. 2 may perform impedance matching using variable reactance elements such as variable capacitors or variable inductors. FIG. 7 is a block diagram of an embodiment of a semiconductor processing system 85 having a processing tool 86 that includes an L-configuration RF impedance matching network 11. As will be discussed in further detail below, the exemplified matching network 11 utilizes electronically variable capacitors (EVCs) for both the shunt variable capacitor 33 and the series variable capacitor 31. It is noted that the invention is not so limited. For example, one of the EVCs (e.g., shunt EVC 33) may be a mechanically variable VVC, or may be replaced with a variable inductor.

The exemplified matching network 11 has an RF input 13 connected to an RF source 15 and an RF output 17 connected to a plasma chamber 19. An RF input sensor 21 can be connected between the RF impedance matching network 11 and the RF source 15. An RF output sensor 49 can be connected between the RF impedance matching network 11 and the plasma chamber 19 so that the RF output from the impedance matching network, and the plasma impedance presented by the plasma chamber 19, may be monitored. Certain embodiments may include only one of the input sensor 21 and the output sensor 49. The functioning of these sensors 21, 49 are described in greater detail below.

As discussed above, the RF impedance matching network 11 serves to help maximize the amount of RF power transferred from the RF source 15 to the plasma chamber 19 by matching the impedance at the RF input 13 to the fixed impedance of the RF source 15. The matching network 11 can consist of a single module within a single housing designed for electrical connection to the RF source 15 and plasma chamber 19. In other embodiments, the components of the matching network 11 can be located in different housings, some components can be outside of the housing, and/or some components can share a housing with a component outside the matching network.

As is known in the art, the plasma within a plasma chamber 19 typically undergoes certain fluctuations outside of operational control so that the impedance presented by the plasma chamber 19 is a variable impedance. Since the variable impedance of the plasma chamber 19 cannot be fully controlled, an impedance matching network may be used to create an impedance match between the plasma chamber 19 and the RF source 15. Moreover, the impedance of the RF source 15 may be fixed at a set value by the design of the particular RF source 15. Although the fixed impedance of an RF source 15 may undergo minor fluctuations during use, due to, for example, temperature or other environmental variations, the impedance of the RF source 15 is still considered a fixed impedance for purposes of impedance matching because the fluctuations do not significantly vary the fixed impedance from the originally set impedance value. Other types of RF source 15 may be designed so that the impedance of the RF source 15 may be set at the time of, or during, use. The impedance of such types of RF sources 15 is still considered fixed because it may be controlled by a user (or at least controlled by a programmable controller) and the set value of the impedance may be known at any time during operation, thus making the set value effectively a fixed impedance.

The RF source 15 generates an RF signal at an appropriate frequency and power for the process performed within the plasma chamber 19. The RF source 15 may be electrically connected to the RF input 13 of the RF impedance matching network 11 using a coaxial cable, which for impedance matching purposes would have the same fixed impedance as the RF source 15.

The plasma chamber 19 includes a first electrode 23 and a second electrode 25, and in processes that are well known in the art, the first and second electrodes 23, 25, in conjunction with appropriate control systems (not shown) and the plasma in the plasma chamber 19, enable one or both of deposition of materials onto a substrate 27 and etching of materials from the substrate 27.

In the exemplified embodiment, the RF impedance matching network 11 includes a series variable capacitor 31, a shunt variable capacitor 33, and a series inductor 35 to form an ‘L’ type matching network. The shunt variable capacitor 33 is shown shunting to a reference potential, in this case ground 40, between the series variable capacitor 31 and the series inductor 35, and one of skill in the art will recognize that the RF impedance matching network 11 may be configured with the shunt variable capacitor 33 shunting to a reference potential at the RF input 13 or at the RF output 17.

Alternatively, the RF impedance matching network 11 may be configured in other matching network configurations, such as a ‘T’ type configuration or a ‘Π’ or ‘pi’ type configuration. In certain embodiments, the variable capacitors and the switching circuit described below may be included in any configuration appropriate for an RF impedance matching network.

In the exemplified embodiment, each of the series variable capacitor 31 and the shunt variable capacitor 33 may be an electronic variable capacitor (EVC), as described in U.S. Pat. No. 7,251,121, the EVC being effectively formed as a capacitor array formed by a plurality of discrete capacitors. The series variable capacitor 31 is coupled in series between the RF input 13 and the RF output 17. The shunt variable capacitor 33 is coupled between the RF input 13 and ground 40. In other configurations, the shunt variable capacitor 33 may be coupled between the RF output 19 and ground 40. Other configurations may also be implemented without departing from the functionality of an RF matching network. In still other configurations, the shunt variable capacitor 33 may be coupled between a reference potential and one of the RF input 13 and the RF output 19.

The series variable capacitor 31 is connected to a series RF choke and filter circuit 37 and to a series driver circuit 39. Similarly, the shunt variable capacitor 33 is connected to a shunt RF choke and filter circuit 41 and to a shunt driver circuit 43. Each of the series and shunt driver circuits 39, 43 are connected to a control circuit 45, which is configured with an appropriate processor and/or signal generating circuitry to provide an input signal for controlling the series and shunt driver circuits 39, 43. A power supply 47 is connected to each of the RF input sensor 21, the series driver circuit 39, the shunt driver circuit 43, and the control circuit 45 to provide operational power, at the designed currents and voltages, to each of these components. The voltage levels provided by the power supply 47, and thus the voltage levels employed by each of the RF input sensor 21, the series driver circuit 39, the shunt driver circuit 43, and the control circuit 45 to perform the respective designated tasks, is a matter of design choice. In other embodiments, a variety of electronic components can be used to enable the control circuit 45 to send instructions to the variable capacitors. Further, while the driver circuit and RF choke and filter are shown as separate from the control circuit 45, these components can also be considered as forming part of the control circuit 45.

In the exemplified embodiment, the control circuit 45 includes a processor (not shown). The processor may be any type of properly programmed processing device (or collection of two or more processing devices working together), such as a computer or microprocessor, configured for executing computer program instructions (e.g., code). The processor may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. The processor of the exemplified embodiment is configured with specific algorithms to enable matching network to perform the functions described herein.

With the combination of the series variable capacitor 31 and the shunt variable capacitor 33, the combined impedances of the RF impedance matching network 11 and the plasma chamber 19 may be controlled, using the control circuit 45, the series driver circuit 39, the shunt driver circuit 43, to match, or at least to substantially match, the fixed impedance of the RF source 15.

The control circuit 45 is the brains of the RF impedance matching network 11, as it receives multiple inputs, from sources such as the RF input sensor 21 and the series and shunt variable capacitors 31, 33, makes the calculations necessary to determine changes to the series and shunt variable capacitors 31, 33, and delivers commands to the series and shunt variable capacitors 31, 33 to create the impedance match. An example algorithm for generating such commands to alter capacitors to create an impedance match is provided below. The control circuit 45 is of the type of control circuit that is commonly used in semiconductor fabrication processes, and therefore known to those of skill in the art. Any differences in the control circuit 45, as compared to control circuits of the prior art, arise in programming differences to account for the speeds at which the RF impedance matching network 11 is able to perform switching of the variable capacitors 31, 33 and impedance matching.

Each of the series and shunt RF choke and filter circuits 37, 41 are configured so that DC signals may pass between the series and shunt driver circuits 39, 43 and the respective series and shunt variable capacitors 31, 33, while at the same time the RF signal from the RF source 15 is blocked to prevent the RF signal from leaking into the outputs of the series and shunt driver circuits 39, 43 and the output of the control circuit 45. The series and shunt RF choke and filter circuits 37, 41 are of a type known to those of skill in the art.

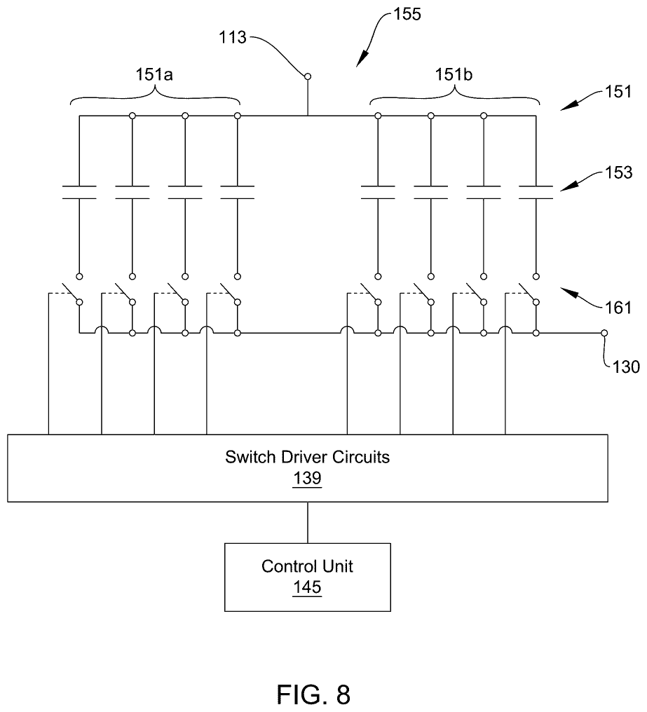

FIG. 8 is a schematic of a variable capacitance system 155 for switching in and out discrete fixed capacitors of an electronically variable capacitor. The variable capacitance system 155 comprises a variable capacitor 151 for providing a varying capacitance. This variable capacitor 151 may be similar to the variable capacitors 31, 33 of FIG. 7. The variable capacitor 151 has an input 113 and an output 130. The variable capacitor 151 includes a plurality of discrete fixed capacitors 153 operably coupled in parallel. The plurality of capacitors 153 includes first (fine) capacitors 151a and second (coarse) capacitors 151b. Further, the variable capacitor 151 includes a plurality of switches 161. Of the switches 161, one switch is operably coupled in series to each of the plurality of capacitors to switch in and out each capacitor, thereby enabling the variable capacitor 151 to provide varying total capacitances. The variable capacitor 151 has a variable total capacitance that is increased when discrete capacitors 153 are switched in and decreased when the discrete capacitors 153 are switched out.

The switches 161 can be coupled to switch driver circuits 139 for driving the switches on and off. The variable capacitance system 155 can further include a control unit 145 operably coupled to the variable capacitor 151. Specifically, the control unit 145 can be operably coupled to the driver circuits 139 for instructing the driver circuits 139 to switch one or more of the switches 161, and thereby turn one or more of the capacitors 153 on or off. In one embodiment, the control unit 145 can form part of a control unit that controls a variable capacitor, such as a control unit that instructs the variable capacitors of a matching network to change capacitances to achieve an impedance match. The driver circuits 139 and control unit 145 can have features similar to those discussed above with reference to FIG. 4, and thus can also utilize an RF choke and filter as discussed above.

It is noted that the control circuit may use a variety of algorithms for enabling an impedance match. As an example, the alteration of the impedance may include determining an impedance of the plasma chamber; determining, based on the impedance of the plasma chamber, a new capacitance value for each of the at least one EVCs; generating a control signal to alter each of the at least one EVCs to the new capacitance value. This process and others are discussed, for example, in co-owned U.S. Pat. No. 11,521,833 (see, e.g., discussion of FIGS. 6 and 7), which is incorporated herein by reference in its entirety.

### Impedance Matching Using Magnetic Coupling

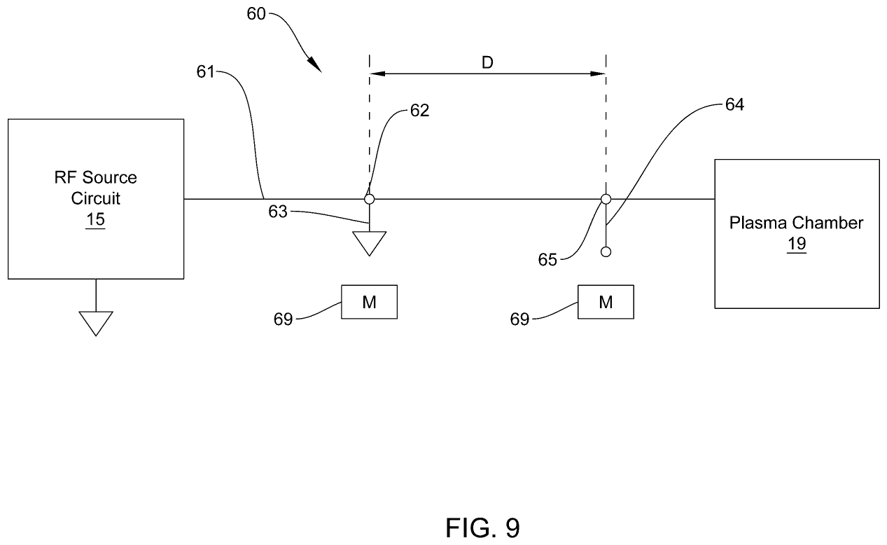

In other embodiments, impedance matching may be performed by other means, such as by using magnetic coupling. FIG. 9 illustrates matching using magnetic coupling. The matching circuit 60 comprises a main power line 61 and coupled lines 63, 64 to the main line. Coupled line 63 is terminated to open circuit, and coupled line 64 is coupled to short circuit. A coupled line may alternatively be terminated at a specified impedance. The main power line and coupled lines may be configured such that the coupling coefficient between the main power line and the coupled lines are varied by altering a magnetic field proximate to the coupled lines. The magnetic field may be provided and altered by, for example, an adjacent DC magnet 69 such as that shown. The alteration of the magnetic field proximate to the coupled lines alters an impedance at a coupled point 62, 65 for each of the coupled lines, which causes the enablement of the impedance match. The coupled lines 63, 64 may be placed along a length of the main power line 61 such that a distance D between each the coupled lines is less than (e.g., a fraction of) a wavelength of any of the RF source signals. It is noted that the invention is not limited to any of these embodiments.

It is noted that impedance matching may also be enabled by altering the frequency of one or more of the RF source signals. This is sometimes referred to as frequency tuning. Frequency tuning may occur alone or in conjunction with a matching network. In other embodiments, the frequency may be substantially fixed (barring minor fluctuations) and impedance matching instead be performed by the matching network without reliance on frequency tuning.

### Method of Controlling Microwave Power

Finally, in another aspect, the invention may be understood as a method to control microwave power delivered to a distributed electrode to improve the uniformity of an electric field on the distributed electrode. The method includes an RF source circuit outputting, at each of multiple RF source circuit outputs, an RF source signal having a frequency of at least 300 MHz. In another operation, for each of the RF source circuit outputs, a solid-state impedance matching circuit receives the RF source signal and electronically alters the matching circuit's impedance to enable an impedance match between the RF source circuit output and a load. In yet another operation, the matching circuit outputs the RF source signals to a distributed electrode of the load.

The embodiments discussed herein provide several advantages. Most significantly, they improve the uniformity of an electric field on the distributed electrode, especially where higher frequency RF signals, such as microwave signals, are used. By causing better electric field uniformity for higher frequency RF sources, the semiconductor fabrication can use these higher frequencies to enable the reduction of film deposition and etch times.

While the inventions have been described with respect to specific examples including presently preferred modes of carrying out the inventions, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

What is claimed is:

1. A system for providing power to a distributed electrode, the system comprising:
a radio frequency (RF) source circuit comprising at least one RF generator and multiple RF source circuit outputs, each RF source circuit output outputting an RF source signal having a frequency of at least 300 MHz;
for each of the RF source circuit outputs, a solid-state impedance matching circuit operably coupled to the RF source circuit output and configured to:
receive the RF source signal output by the RF source circuit output; and
electronically alter its impedance to enable an impedance match between the RF source circuit output and a load; and
for each of the matching circuits, a system output operably coupled to the matching circuit and configured to output the RF source signal to a distributed electrode of the load.

2. The system of claim 1, wherein the RF source circuit comprises at least two RF generators, and wherein each RF source signal is originated by a separate one of the RF generators.

3. The system of claim 1, wherein the RF source circuit comprises: a splitter receiving a signal from one of the at least one RF generator and splits the signal into multiple signals that are provided to multiple phase adjuster circuits.

4. The system of claim 1:
wherein the RF source circuit comprises at least two RF generators; and
wherein one of the at least two RF generators provides output phase information to the others of the at least two RF generators to enable phase control.

5. The system of claim 1, wherein each generator comprises an amplifier configured to amplify a received RF signal, and wherein each of the amplifiers is controlled by a common control circuit.

6. The system of claim 1, wherein the RF source circuit further comprises a frequency source and a phase adjuster circuit, the frequency source configured transmit a signal to the phase adjuster circuit, the phase adjust circuit configured to output to each of the at least one RF generators a separate RF signal, each of the separate RF signals having a different phase; wherein the phase adjuster circuit is upstream of the at least one RF generator, and wherein the phase adjuster circuit is configured to phase lock the phase of each RF source signal.

7. The system of claim 6, wherein the phase adjuster circuit is configured to adjust the phase of each RF source signal on phase-related information obtained from either:
the distributed electrode;
an output of one or more of the matching circuits;
an input of one or more of the matching circuits;
an output of one or more of the at least one RF generator; or
an input of one or more of the at least one RF generator.

8. The system of claim 1, wherein each of the impedance matching circuits comprises at least one electronically variable reactance element (EVRE), the EVRE configured to electronically vary its reactance to enable the impedance match.

9. The system of claim 8, wherein, for each of the impedance matching circuits, the at least one EVRE is at least one electronically variable capacitor (EVC) comprising:
fixed capacitors; and
for each fixed capacitor, a corresponding switch configured to switch in and out the fixed capacitor to alter a total capacitance of the EVC.

10. The system of claim 9, wherein the electronic alteration of the impedance to enable an impedance match comprises:
determining an impedance of the plasma chamber;
determining, based on the impedance of the plasma chamber, a new capacitance value for each of the at least one EVCs; and
generating a control signal to alter each of the at least one EVCs to the new capacitance value.

11. The system of claim 1, wherein the distributed electrode comprises an electrode comprising multiple feeds at different locations on the electrode, each of the feeds receiving a separate one of the RF source signals.

12. The system of claim 1, wherein the distributed electrode comprises a plurality of electrode segments adjacent to one another and separated by dielectric material, each of the plurality of electrode segments receiving a separate one of the RF source signals.

13. The system of claim 1, wherein the distributed electrode receives the RF source signals via a conductor operably coupled to the system output, the conductor being directly physically connected to the distributed electrode.

14. The system of claim 1, wherein the distributed electrode receives the RF source signals via a conductor operably coupled to the system output that is positioned in close proximity to the distributed electrode without the conductor physically contacting the distributed electrode.

15. The system of claim 1:
wherein the load is a plasma chamber configured to deposit a material onto a substrate or etch a material from the substrate;
wherein the plasma chamber comprises two electrodes;
wherein the distributed electrode is one of the two electrodes; and
wherein plasma is generated between the two electrodes by the RF source signals received by the distributed electrode.

16. The system of claim 1, wherein each RF source signal has a frequency between 2 GHz and 3 GHz.

17. The system claim 1, wherein each matching circuit comprises a main power line and coupled lines to the main line, wherein the coupled lines are terminated to either open circuit, short circuit, or a specified impedance.

18. The system of claim 17, wherein the main power line and the coupled lines are configured such that the coupling coefficient between the main power line and the coupled lines are varied by altering a magnetic field proximate to the coupled lines.

19. The system of claim 17, wherein the alteration of the magnetic field proximate to the coupled lines alters an impedance at a coupled point for each of the coupled lines.

20. The system of claim 17:
wherein each matching circuit comprises a main power line and coupled lines to the main line; and
wherein the coupled lines are placed along a length of the main power line such that a distance between each the coupled lines is less than a wavelength of any of the RF source signals.
